(19) United States
(12) Patent Application Publication
(10) Pub. No.: US 2025/0287760 A1
(43) Pub. Date: Sep. 11, 2025

(54) LIGHT EMITTING DEVICE, IMAGE CAPTURING DEVICE, ELECTRONIC APPARATUS, AND WEARABLE DEVICE

(71) Applicant: CANON KABUSHIKI KAISHA, Tokyo (JP)

(72) Inventors: KOJI ISHIZUYA, Kanagawa (JP); TETSUO TAKAHASHI, Kanagawa (JP); SHOMA HINATA, Kanagawa (JP); YUHI UEDA, Kanagawa (JP)

(21) Appl. No.: 19/059,796

(22) Filed: Feb. 21, 2025

(30) Foreign Application Priority Data
Mar. 8, 2024 (JP) 2024-036267

(51) Int. Cl. H10H 29/856; H10H 29/80

(52) U.S. Cl. CPC H10H 29/856; H10H 29/8325

(57) ABSTRACT

Light emitting device includes first and second light emitting elements for visible light and third light emitting element for infrared light. Distance from upper surface of reflective layer of the first light emitting element to upper surface of lower electrode of the first light emitting element is different from distance from upper surface of reflective layer of the second light emitting element to upper surface of lower electrode of the second light emitting element. The distance from the upper surface of the reflective layer of the first light emitting element to the upper surface of the lower electrode of the first light emitting element is substantially equal to distance from upper surface of reflective layer of the third light emitting element to upper surface of lower electrode of the third light emitting element.

### BACKGROUND OF THE INVENTION

### Field of the Invention

The present invention relates to a light emitting device, an image capturing device, an electronic apparatus, and a wearable device.

### Description of the Related Art

An organic light emitting device is a device that causes a light emitting layer including an organic compound layer to emit light by applying a voltage thereto. Since the organic light emitting device is a self-light emitting device, it need not separately include a light source and a display control unit such as a shutter, like a liquid crystal display device. Accordingly, the organic light emitting device has an advantage that it can achieve a smaller thickness and less power consumption than the liquid crystal display device. Therefore, the organic light emitting device is attracting attention as a display device for a camera viewfinder, a head mounted display, a wearable device called smartglasses, or the like.

In such a display device, it is desired to detect the gazing point of a user by detecting the line of sight of the user with respect to a display unit. The information of the detected gazing point can be reflected on driving of the display device. As a method of detecting the line of sight of a user, there is a method of irradiating the eyeball of a user viewing the display device with infrared light and detecting the reflected image of the eyeball of the user. Further, in order to reduce the power consumption of the display unit of the display device, there is known a method of changing the optical distance for each light emission color to improve light emission efficiency.

Japanese Patent Laid-Open No. 2021-15731 discloses a technique of providing a light emitting element constituting a display unit and an infrared light emitting element for emitting infrared light in the same substrate. Japanese Patent Laid-Open No. 2021-15731 also discloses that the optical distance (the distance between reflective surfaces) is changed between the display element and the infrared light emitting element. Japanese Patent Laid-Open No. 2005-116516 discloses that the optical distance of a resonator structure including a mirror and a half mirror is changed for each light emission color.

If the configuration disclosed in Japanese Patent Laid-Open No. 2005-116516 is used in the infrared light emitting element disclosed in Japanese Patent Laid-Open No. 2021-15731 to make the optical distance of the light emitting element configured to emit infrared light different from a plurality of optical distances of light emitting elements configured to emit visible light, this leads to an increase in the number of steps.

### SUMMARY OF THE INVENTION

The present invention provides a technique advantageous in improving the light emission efficiency of each of a light emitting element configured to emit visible light and a light emitting element configured to emit infrared light while suppressing an increase in the number of steps.

The first aspect of the present invention provides a light emitting device having a plurality of light emitting elements including a first light emitting element and a second light emitting element each configured to emit visible light and a third light emitting element configured to emit infrared light, wherein each of the plurality of light emitting elements includes a reflective layer, a lower electrode arranged on the reflective layer, a light emitting layer arranged on the lower electrode, and an upper electrode arranged on the light emitting layer, a distance from an upper surface of the reflective layer of the first light emitting element to an upper surface of the lower electrode of the first light emitting element is different from a distance from an upper surface of the reflective layer of the second light emitting element to an upper surface of the lower electrode of the second light emitting element, and the distance from the upper surface of the reflective layer of the first light emitting element to the upper surface of the lower electrode of the first light emitting element is substantially equal to a distance from an upper surface of the reflective layer of the third light emitting element to an upper surface of the lower electrode of the third light emitting element.

Further features of the present invention will become apparent from the following description of exemplary embodiments with reference to the attached drawings.

### BRIEF DESCRIPTION OF THE DRAWINGS

FIG. 1 is a sectional view schematically showing the arrangement of a light emitting device according to the first embodiment.

FIG. 2 is a sectional view schematically showing the arrangement of a light emitting device according to the second embodiment.

FIG. 3 is a sectional view schematically showing the arrangement of a light emitting device according to the third embodiment.

FIG. 4 is a sectional view schematically showing the arrangement of a light emitting device according to the fourth embodiment.

FIG. 5 is a sectional view schematically showing the arrangement of a light emitting device according to the fifth embodiment.

FIG. 6 is a sectional view schematically showing the arrangement of a light emitting device according to the sixth embodiment.

FIG. 7 is a view showing an application example of the light emitting device.

FIGS. 8A and 8B are views each showing an application example of the light emitting device.

FIGS. 9A and 9B are views each showing an application example of the light emitting device.

FIGS. 10A and 10B are views each showing an application example of the light emitting device.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

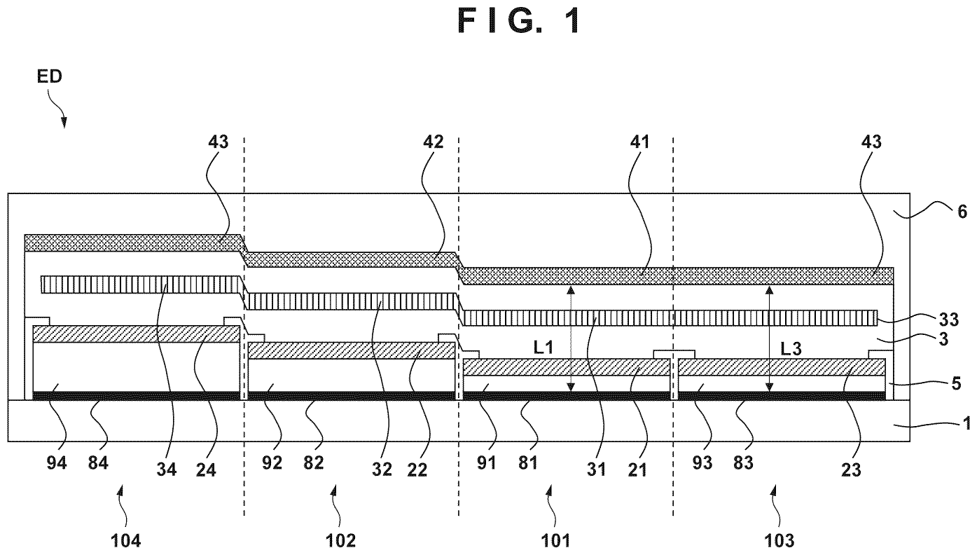

FIG. 1 is a sectional view schematically showing the arrangement of a light emitting device ED according to the first embodiment. The light emitting device ED can have a function of displaying an image and a function of radiating infrared light. In the description of the structure of the light emitting device ED, directions such as “up” and “down” follow the directions of “up” and “down” on the paper surface of FIG. 1. In another viewpoint, the direction from an organic compound layer 3 toward a substrate 1 corresponds to “down”, and the direction from the substrate 1 toward the organic compound layer 3 correspond to “up”.

The light emitting device ED can include the substrate 1. The substrate 1 can be formed of a material that can support a plurality of light emitting elements formed thereon. For example, a glass substrate, a plastic substrate, a semiconductor substrate (for example, a silicon substrate), or the like can be used as the substrate 1. The substrate 1 may include a switching element (not shown) such as a transistor, a wiring pattern, a via, an interlayer insulating film, and the like. The transistor may be a MOS transistor including a portion formed in the semiconductor substrate, or may be a TFT.

The light emitting device ED includes a plurality of light emitting elements. The plurality of light emitting elements can include at least a first light emitting element 101 and a second light emitting element 102 that emit visible light, and a third light emitting element 103 that emits infrared light. Note that the ordinal numbers such as first and second are merely used to distinguish the components to which the ordinal numbers are attached, and do not indicate features, properties, or the like.

Each of the plurality of light emitting elements includes a reflective layer, a lower electrode arranged on the reflective layer, a light emitting layer arranged on the lower electrode, and an upper electrode arranged on the light emitting layer. In other words, the first light emitting element 101 includes a first reflective layer 81, a first lower electrode 21 arranged on the first reflective layer 81, a first light emitting layer 31 arranged on the first lower electrode 21, and a first upper electrode 41 arranged on the first light emitting layer 31. The second light emitting element 102 includes a second reflective layer 82, a second lower electrode 22 arranged on the second reflective layer 82, a second light emitting layer 32 arranged on the second lower electrode 22, and a second upper electrode 42 arranged on the second light emitting layer 32. The third light emitting element 103 includes a third reflective layer 83, a third lower electrode 23 arranged on the third reflective layer 83, a third light emitting layer 33 arranged on the third lower electrode 23, and a third upper electrode 43 arranged on the third light emitting layer 33.

The lower electrodes such as the first lower electrode 21, the second lower electrode 22, and the third lower electrode 23 are preferably formed of a light transmissive material from the viewpoint of light emission efficiency. More specifically, the lower electrode can be formed of a thin film of a transparent conductive oxide such as ITO or IZO, a metal such as Al, Ag, Pt, Au, or Ti, an alloy thereof, or a compound thereof.

The light emitting layers such as the first light emitting layer 31, the second light emitting layer 32, and the third light emitting layer 33 can form a part of the organic compound layer 3. The organic compound layer 3 can be arranged on the lower electrodes such as the first lower electrode 21, the second lower electrode 22, and the third lower electrode 23. The organic compound layer 3 can be formed by, for example, a vapor deposition method, a spin coating method, an inkjet method, or the like. The organic compound layer 3 may be constituted by a plurality of layers, and can include, for example, a hole injection layer, a hole transport layer, an electron blocking layer, a hole blocking layer, an electron transport layer, an electron injection layer, a charge generation layer, and the like, in addition to the light emitting layer. The light emitting layer can be arranged between the electron blocking layer and the hole blocking layer. The arrangement of the organic compound layer 3 is not particularly limited, and a layer other than the layers described above may be further included. Each layer constituting the organic compound layer 3 may be formed from a plurality of films, and the light emitting layer may include a plurality of light emitting films. If the light emitting layer includes a plurality of light emitting films, the respective light emitting films may be stacked in contact with each other, or may be stacked via another film.

The light emitting layer contains a light emitting material. The light emitting material is, for example, one of a blue light emitting material, a green light emitting material, a red light emitting material, and an infrared light emitting material. If the light emitting layer includes a plurality of light emitting films, one light emitting film may contain one kind of light emitting material. Alternatively, one light emitting film may contain two or more kinds of light emitting materials. The light emitting layer may be commonly provided on the lower electrodes such as the first lower electrode 21, the second lower electrode 22, and the third lower electrode 23, or may be individually provided for each lower electrode. Alternatively, a light emitting layer may be commonly provided on the first lower electrode 21, the second lower electrode 22, and the third lower electrode 24, and another light emitting layer may be provided on the third lower electrode 23.

Each of the first light emitting layer 31 of the first light emitting element 101 and the second light emitting layer 32 of the second light emitting element 102 can contain one of the blue light emitting material, the green light emitting material, and the red light emitting material. Alternatively, they can contain light emitting materials that emit visible light beams in a plurality of bands different from each other. The third light emitting layer 33 of the third light emitting element (infrared light emitting element) 103 contains at least the infrared light emitting material. Accordingly, the first light emitting element 101 and the second light emitting element 102 emit visible light, and the third light emitting element (infrared light emitting element) 103 emits infrared light.

The upper electrodes such as the first upper electrode 41, the second upper electrode 42, and the third upper electrode 43 are arranged on the organic compound layer 3, and have light transmissivity. Each upper electrode can be formed of a semi-transmissive material having the property (that is, semi-transmissive reflectivity) of transmitting part of light having reached its surface and reflecting other part of the light. Each upper electrode can be formed of, for example, a transparent material such as a transparent conductive oxide, an elemental metal such as aluminum, silver, or gold, an alkali metal such as lithium or cesium, or an alkaline earth metal such as magnesium, calcium, or barium. Alternatively, each upper electrode can be formed of a semi-transmissive material made of an alloy material containing one of these metal materials. The semi-transmissive material is preferably an alloy particularly containing magnesium or silver as the principal component. As long as the preferable transmittance is provided, each upper electrode may have a stacked structure of the above-described materials. The first upper electrode 41, the second upper electrode 42, and the third upper electrode 43 may be commonly or individually provided to the first light emitting element 101, the second light emitting element 102, and the third light emitting element 103.

The reflective layers such as the first reflective layer 81, the second reflective layer 82, and the third reflective layer 83 are formed of a material having high reflectivity, and may be formed of a metal material such as, in particular, Al, Ag, Ti, W, Mo, Au, Ni, or Pt, or an alloy of the materials described above, or may have a stacked structure thereof. The reflective layers such as the first reflective layer 81, the second reflective layer 82, and the third reflective layer 83 are preferably formed of the same material. It is preferable that the distance from the upper surface of the substrate 1 to the lower surface of each of the reflective layers such as the first reflective layer 81, the second reflective layer 82, and the third reflective layer 83 is substantially the same among the reflective layers.

A first light transmitting layer 91 can be provided between the first reflective layer 81 and the first lower electrode 21, a second light transmitting layer 92 can be provided between the second reflective layer 82 and the second lower electrode 22, and a third light transmitting layer 93 can be provided between the third reflective layer 83 and the third lower electrode 23. The light transmitting layers such as the first light transmitting layer 91, the second light transmitting layer 92, and the third light transmitting layer 93 are formed of a material that transmits light, and particularly preferably formed of SiO, SiN, or SiON. The light transmitting layer can be formed by, for example, a sputtering method, a CVD method, or an ALD method.

In the first embodiment, the distance from the upper surface of the first reflective layer 81 to the upper surface of the first lower electrode 21 in the first light emitting element 101 is different from the distance from the upper surface of the second reflective layer 82 to the upper surface of the second lower electrode 22 in the second light emitting element 102. Further, in the first embodiment, the distance from the upper surface of the first reflective layer 81 to the upper surface of the first lower electrode 21 in the first light emitting element 101 is substantially equal to the distance from the upper surface of the third reflective layer 83 to the upper surface of the third lower electrode 23 in the third light emitting element (infrared light emitting element) 103. Here, the expression “substantially equal to” means that the ratio of the larger value to the smaller value of two values is within 1.05. This is so because manufacturing variations are taken into consideration.

Here, the distance from the upper surface of the first reflective layer 81 of the first light emitting element 101 to the upper surface of the first lower electrode 21 may be defined as the first distance. The distance from the upper surface of the second reflective layer 82 of the second light emitting element 102 to the upper surface of the second lower electrode 22 may be defined as the second distance. The distance from the upper surface of the third reflective layer 83 of the third light emitting element 103 to the upper surface of the third lower electrode 23 may be defined as the third distance. Explaining according to these definitions, the light emitting device ED according to the first embodiment has an aspect in which the difference between the first distance and the third distance is smaller than the difference between the first distance and the second distance.

In the present invention, the film thickness of each of the first light transmitting layer 91, the second light transmitting layer 92, the third light transmitting layer 93, the first lower electrode 21, the second lower electrode 22, and the third lower electrode 23 is not particularly limited as long as the above-described conditions are satisfied.

In the first embodiment, the film thicknesses of the first lower electrode 21, the second lower electrode 22, and the third lower electrode 23 are substantially equal to each other. Further, in the first embodiment, the film thicknesses of the first light transmitting layer 91 and the second light transmitting layer 92 are different from each other, and the film thicknesses of the first light transmitting layer 91 and the third light transmitting layer 93 are substantially equal to each other. By forming the film thickness of each of the first light transmitting layer 91, the second light transmitting layer 92, and the third light transmitting layer 93 to the film thickness suitable for the corresponding light emitting element, the light emission efficiency of each of the first light emitting element 101, the second light emitting element 102, and the third light emitting element (infrared light emitting element) 103 can be improved.

On the other hand, the film thicknesses of the first lower electrode 21 and the third lower electrode 23 are substantially equal to each other, and the film thicknesses of the first light transmitting layer 91 and the third light transmitting layer 93 are substantially equal to each other. Hence, in the manufacture of the light emitting device ED, the light transmitting layer and lower electrode of the first light emitting element 101 can be formed in the same steps as those of the third light emitting element 103, respectively. Further, by forming the film thickness of the first light transmitting layer 91 to be different from the film thickness of the second light transmitting layer 92, it is possible to change the chromaticity between the first light emitting element 101 and the second light emitting element 102. Accordingly, multi-color display in the display region is possible.

Therefore, according to the first embodiment, it is possible to improve the light emission efficiency of each of the first light emitting element 101 and the third light emitting element (infrared light emitting element) 103 while suppressing an increase in the number of steps in the manufacture, and perform multi-color display.

According to the first embodiment, letting ND3 be the optical distance from the upper surface of the third reflective layer 83 to the lower surface of the third upper electrode 43 of the third light emitting element (infrared light emitting element) 103, it is preferable that ND3 satisfies a condition expressed by:

$$ND 31 \leq ND 3 \leq ND 32 ND 31 = - φ3 / 4 π \times λ3 \times 0.9 ND 32 = - φ3 / 4 π \times λ3 \times 1.1 \qquad ( 1 )$$

where φ3 is the sum of the phase shifts in the third reflective layer 83 and the third upper electrode 43, and λ3 is the peak wavelength of the PL emission spectrum of the infrared light emitting material contained in the third light emitting layer 33.

In order to satisfy the condition expressed by formula (1), letting L3 be the distance from the upper surface of the third reflective layer 83 of the third light emitting element (infrared light emitting element) 103 to the lower surface of the third upper electrode 43, it is particularly preferable that L3 and λ3 satisfy a condition expressed by:

$$0.2 \leq λ3 / L 3 \leq 0.30 \qquad ( 2 )$$

Further, L3 is preferably 160 nm or more and 300 nm or less.

By satisfying the conditions expressed by formulas (1) and (2), the light emission efficiency of the third light emitting element (infrared light emitting element) 103 can be improved.

λ3 is preferably 800 nm or more and 1,000 nm or less.

Letting ND1 be the optical distance from the upper surface of the first reflective layer 81 of the first light emitting element 101 to the lower surface of the first upper electrode 41, it is particularly preferable that ND1 satisfies a condition expressed by:

$$ND 11 \leq ND 1 \leq ND 12 ND 11 = ( 1 - φ1 / 2 π ) \times λ1 \times 0.9 ND 12 = ( 1 - φ1 / 2 π ) \times λ1 \times 1.1 \qquad ( 3 )$$

where φ1 is the sum of the phase shifts in the first reflective layer 81 and the first upper electrode 41, and λ1 is the peak wavelength of the PL emission spectrum of the light emitting material contained in the first light emitting layer 31.

In order to satisfy the condition expressed by formula (3), letting L1 be the distance from the upper surface of the first reflective layer 81 of the first light emitting element 101 to the lower surface of the first upper electrode 41, it is particularly preferable that L1 and 21 satisfy a condition expressed by:

$$0.45 \leq λ1 / L 1 \leq 0.65 \qquad ( 4 )$$

By satisfying the conditions expressed by formulas (3) and (4), the light emission efficiency of the first light emitting element 101 can be improved.

As described above, in the first embodiment, the distance from the upper surface of the first reflective layer 81 to the upper surface of the first lower electrode 21 in the first light emitting element 101 is substantially equal to the distance from the upper surface of the third reflective layer 83 to the upper surface of the third lower electrode 23 in the third light emitting element 103. In this case, the first light emitting layer 31 of the first light emitting element 101 preferably contains the blue light emitting material. This is because if the first light emitting layer 31 contains the blue light emitting material, the light emission efficiencies of both the first light emitting element and the third light emitting element can be easily improved.

The light emitting device ED can include an insulating layer 5 between the lower electrodes of the light emitting elements adjacent to each other. The insulating layer 5 can include an opening such that the insulating layer 5 covers the peripheral portion in the lower electrode and exposes the inside of the peripheral portion. For example, the first light emitting element 101 and the third light emitting element 103 are arranged adjacent to each other, and the first lower electrode 21 of the first light emitting element 101 and the third lower electrode 23 of the third light emitting element 103 can be separated from each other by the insulating layer 5. The insulating layer 5 between the first lower electrode 21 and the third lower electrode 23 can have a T-shape in a section (a section cutting the reflective layer, the lower electrode, the light emitting layer, and the upper electrode) shown in FIG. 1. The insulating layer 5 between the first lower electrode 21 and the third lower electrode 23 can have a flat upper surface.

The first light emitting element 101 and the second light emitting element 102 may be arranged adjacent to each other, and the first lower electrode 21 of the first light emitting element 101 and the second lower electrode 22 of the second light emitting element 102 can be separated from each other by the insulating layer 5. The insulating layer 5 between the first lower electrode 21 and the second lower electrode 22 can have a step corresponding to the height difference between the upper surface of the first lower electrode 21 and the upper surface of the second lower electrode 22.

The upper surface of the lower electrode (the inside of the peripheral portion thereof) can contact the lower surface of the organic compound layer 3 through the opening of the insulating layer 5. The opening of the insulating layer 5 has a function of defining the light emitting region of the light emitting element, and this is useful for forming the light emitting region into an accurate desirable shape. The insulating layer 5 can also have a function of electrically insulating the lower electrodes of two adjacent light emitting elements from each other. The insulating layer 5 can also be called a pixel separation layer (PDL), a partition wall, a bank, or the like. If the insulating layer 5 is not provided, the light emitting region can be defined by the shape of the lower electrode.

The insulating layer 5 is preferably formed of an inorganic material such as silicon nitride (SiN), silicon oxynitride (SiON), or silicon oxide (SiO). The insulating layer 5 can be formed by a method such as a sputtering method or a chemical vapor deposition method (CVD method). The insulating layer 5 may be formed of an organic material such as acrylic resin or polyimide resin.

The light emitting device ED may include a sealing layer 6 formed to cover the organic compound layer 3 and the upper electrodes. The sealing layer 6 has light transmissivity, and preferably contains an inorganic material having low permeability for oxygen and water from the outside. Silicon nitride (SiN), silicon oxynitride (SiON), silicon oxide (SiO), aluminum oxide (Al₂O₃), or titanium oxide (TiO₂) is preferable as the inorganic material contained in the sealing layer 6. Among these, it is preferable that the sealing layer 6 contains SiN, SiON, or Al₂O₃ from the viewpoint of enhancing sealing performance. The sealing layer 6 can be formed by a chemical vapor deposition method (CVD method), an atomic layer deposition method (ALD method), a sputtering method, or an ion plating method. As long as the sufficient water blocking performance is provided, the sealing layer 6 may have a single-layer structure or a stacked structure of a plurality of films each formed by an arbitrary combination of the above-described materials and forming methods. The sealing layer 6 may have a stacked structure of an inorganic material and an organic material such as a resin. The continuous sealing layer 6 may be formed so as to cover all of the upper electrodes of the plurality of light emitting elements.

So far, an example has been described in which the light emitting device ED includes the first light emitting element 101, the second light emitting element 102, and the third light emitting element 103, but the light emitting device ED may include a fourth light emitting element 104 that emits visible light. The fourth light emitting element 104 includes a fourth reflective layer 84, a fourth lower electrode 24 arranged on the fourth reflective layer 84, a fourth light emitting layer 34 arranged on the fourth lower electrode 24, and a fourth upper electrode 44 arranged on the fourth light emitting layer 34. The distance from the upper surface of the fourth reflective layer 84 to the upper surface of the fourth lower electrode 24 is preferably different from the distance from the upper surface of the first reflective layer 81 to the upper surface of the first lower electrode 21 and the distance from the upper surface of the second reflective layer 82 to the upper surface of the second lower electrode 22. By changing the distances, the chromaticities of the first light emitting element 101, the second light emitting element 102, and the fourth light emitting element 104 can be made different, thereby improving light emission efficiency. By configuring the first light emitting element 101, the second light emitting element 102, and the fourth light emitting element 104 as blue, green, and red light emitting elements, respectively, full color display is possible.

Each of the first light emitting element 101, the second light emitting element 102, the fourth light emitting element 104, and the infrared light emitting element 103 can be regarded as a sub-pixel, and the four light emitting elements can be regarded as constituting one main pixel. The array of the sub-pixels in the main pixel may be any array such as a stripe array or a Bayer array. A display device can be formed by arraying a plurality of main pixels in a display plane.

In the first embodiment, the fourth light emitting element 104 can be a red light emitting element that emits red light. The distance from the upper surface of the third reflective layer 83 to the upper surface of the third lower electrode 23 in the third light emitting element 103 as the infrared light emitting element is smaller than the distance from the upper surface of the fourth reflective layer 84 to the upper surface of the fourth lower electrode 24 in the fourth light emitting element 104 as the red light emitting element. In the first embodiment, the first light emitting element 101 can be a blue light emitting element that emits blue light, and the second light emitting element 102 can be a green light emitting element that emits green light.

The second light emitting element 102 and the fourth light emitting element 104 may be arranged adjacent to each other, and the second lower electrode 22 of the second light emitting element 102 and the fourth lower electrode 24 of the fourth light emitting element 104 can be separated from each other by the insulating layer 5. The insulating layer 5 between the second lower electrode 22 and the fourth lower electrode 24 can have a step corresponding to the height difference between the upper surface of the second lower electrode 22 and the upper surface of the fourth lower electrode 24.

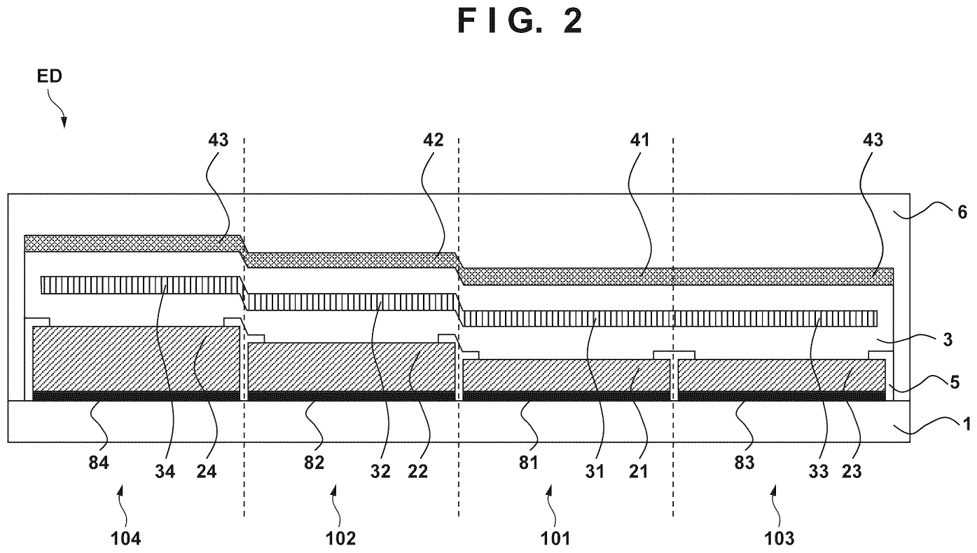

The second embodiment will be described below. FIG. 2 is a sectional view schematically showing the arrangement of a light emitting device ED according to the second embodiment. Matters not mentioned as the second embodiment can follow the first embodiment.

Also in the second embodiment, the distance from the upper surface of a first reflective layer 81 to the upper surface of a first lower electrode 21 in a first light emitting element 101 and the distance from the upper surface of a second reflective layer 82 to the upper surface of a second lower electrode 22 in a second light emitting element 102 are different from each other. Further, the distance from the upper surface of the first reflective layer 81 to the upper surface of the first lower electrode 21 in the first light emitting element 101 and the distance from the upper surface of a third reflective layer 83 to the upper surface of a third lower electrode 23 in a third light emitting element (infrared light emitting element) 103 are substantially equal to each other.

In the second embodiment, the film thicknesses of the first lower electrode 21 and the second lower electrode 22 are different from each other, and the film thicknesses of the first lower electrode 21 and the third lower electrode 23 are substantially equal to each other. This can implement a shape in which the distance from the upper surface of the first reflective layer 81 to the upper surface of the first lower electrode 21 and the distance from the upper surface of the second reflective layer 82 to the upper surface of the second lower electrode 22 are different from each other. On the other hand, the distance from the upper surface of the first reflective layer 81 to the upper surface of the first lower electrode 21 and the distance from the upper surface of the third reflective layer 83 to the upper surface of the third lower electrode 23 are substantially equal to each other.

In each light emitting element, the reflective layer and the lower electrode may be in contact with each other, but a light transmitting layer may be arranged between the reflective layer and the lower electrode. If the light transmitting layer is arranged between the reflective layer and the lower electrode, it is preferable that the light transmitting layers of the plurality of light emitting elements have substantially the same film thickness.

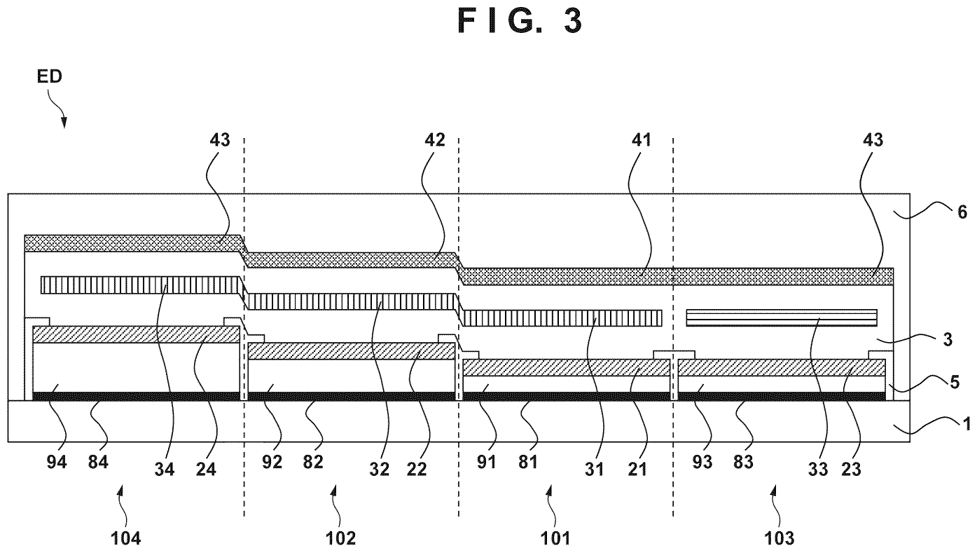

The third embodiment will be described below. FIG. 3 is a sectional view schematically showing the arrangement of a light emitting device ED according to the third embodiment. Matters not mentioned as the third embodiment can follow the first or second embodiment.

In the third embodiment, a first light emitting layer 31 of a first light emitting element 101 and a third light emitting layer 33 of a third light emitting element (infrared light emitting element) 103 are separated. In addition, in the third embodiment, a second light emitting layer 32 of a second light emitting element 102 and the third light emitting layer 33 of the third light emitting element (infrared light emitting element) 103 are separated. If a fourth light emitting element 104 is provided, a fourth light emitting layer 34 of the fourth light emitting element 104 and the third light emitting layer 33 of the third light emitting element (infrared light emitting element) 103 are separated. From another viewpoint, in the third embodiment, the light emitting layer of the light emitting element for displaying an image and the light emitting layer of the light emitting element that emits infrared light are separated. This arrangement is advantageous in increasing the light emission efficiency of each light emitting element.

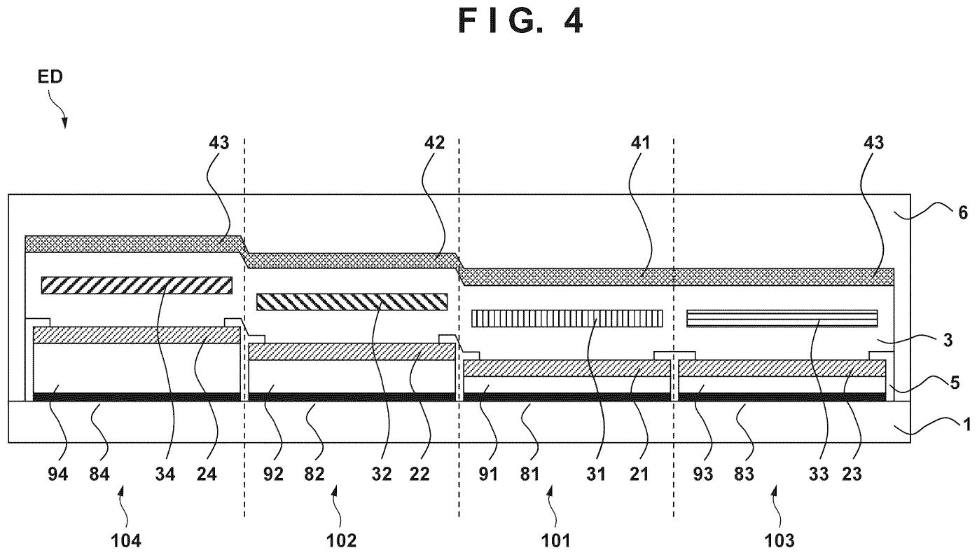

The fourth embodiment will be described below. FIG. 4 is a sectional view schematically showing the arrangement of a light emitting device ED according to the fourth embodiment. Matters not mentioned as the fourth embodiment can follow the first or second embodiment.

In the fourth embodiment, light emitting layers adjacent to each other can be separated from each other. For example, a first light emitting layer 31 of a first light emitting element 101 and a second light emitting layer 32 of a second light emitting element 102 can be separated from each other. If a fourth light emitting element 104 is provided, the second light emitting layer 32 of the second light emitting element 102 and a fourth light emitting layer 34 of the fourth light emitting element 104 can be separated. A third light emitting layer 33 of a third light emitting element 103 can also be separated from the light emitting layers of the other light emitting elements. This arrangement is advantageous in increasing the light emission efficiency of each light emitting element.

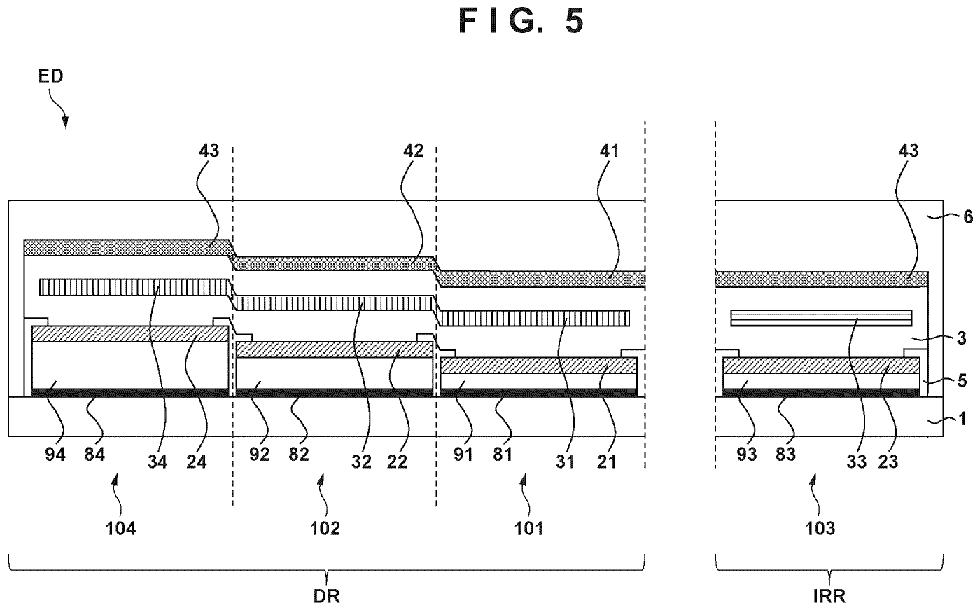

The fifth embodiment will be described below. FIG. 5 is a sectional view schematically showing the arrangement of a light emitting device ED according to the fifth embodiment. Matters not mentioned as the fifth embodiment can follow the first to fourth embodiments.

The light emitting device ED according to the fifth embodiment includes a display region DR and an infrared light radiation region IRR. The infrared light radiation region IRR is arranged outside the display region DR. A plurality of first light emitting elements 101, a plurality of second light emitting elements 102, and a plurality of fourth light emitting elements 103 can be arranged in the display region DR. One or a plurality of third light emitting elements (infrared light emitting elements) 103 can be arranged in the infrared light radiation region IRR. This arrangement is advantageous in increasing the area (pixel area) of each of the first light emitting element 101, the second light emitting element 102, and the fourth light emitting element 104 in the display region DR. This can suppress, for example, deterioration in luminance of the light emitting element caused by driving of the light emitting element.

Each of the first light emitting element 101, the second light emitting element 102, and the fourth light emitting element 104 can be regarded as a sub-pixel, and the three light emitting elements can be regarded as constituting one main pixel. The pixel array of the sub-pixels in the main pixel may be any pixel array such as a delta array, a stripe array, or a Bayer array. In particular, the delta array is preferable because it facilitates arrangement of a circular lens in the display region DR.

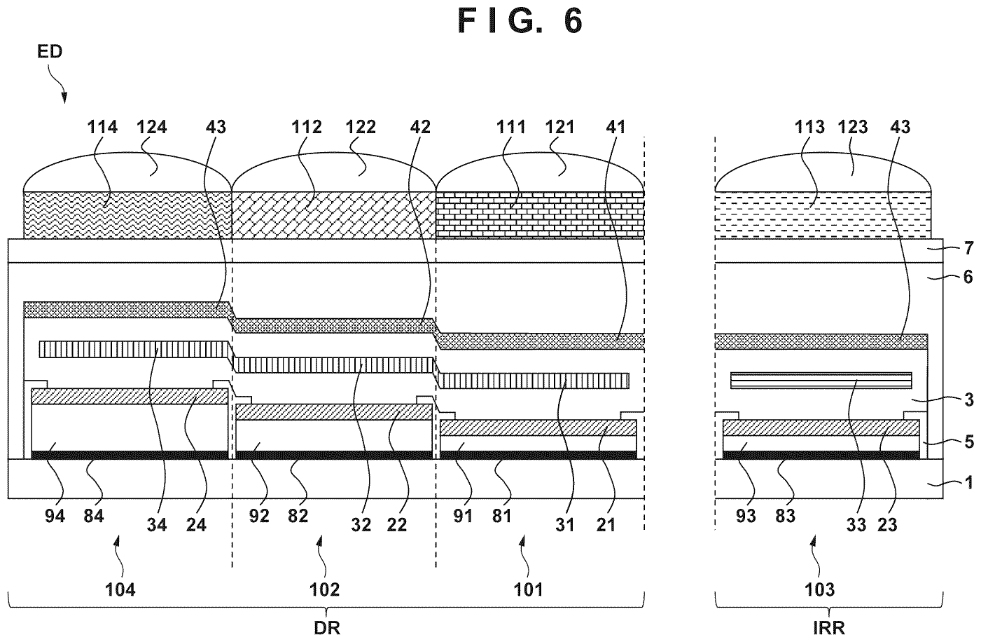

The sixth embodiment will be described below. FIG. 6 is a sectional view schematically showing the arrangement of a light emitting device ED according to the sixth embodiment. Matters not mentioned as the sixth embodiment can follow the first to fifth embodiments.

In the sixth embodiment, a planarizing layer 7 can be arranged on a sealing layer 6. The planarizing layer 7 is preferably formed by, for example, a wet process such as a spin coating method, a dip coating method, a slit coating method, or a blade coating method. The wet process is advantageous in planarizing the light emission surface of the planarizing layer 7. When forming the planarizing layer 7 formed by the wet process, after a material for forming the planarizing layer 7 is arranged or applied on the sealing layer 6, the material is preferably cured by a curing method such as heating or UV irradiation. The planarizing layer 7 can be a continuous planarizing film covering all of the sealing layers 6 of a plurality of light emitting elements.

A first color filter 111, a second color filter 112, a fourth color filter 114, and an infrared color filter 113 may be provided on a first light emitting element 101, a second light emitting element 102, a fourth light emitting element 104, and an infrared light emitting element 103, respectively. The wavelength range of light to be transmitted can be adjusted in each of first color filter 111, the second color filter 112, the fourth color filter 114, and the infrared color filter 113. Each color filter can be formed by applying a color resist onto the planarizing film 7 and then patterning it by lithography. The color resist is made of, for example, a photocurable resin, and a pattern can be formed by curing the portion irradiated with ultraviolet light or the like.

A first lens 121, a second lens 122, a fourth lens 124, and a third lens 123 may be provided on the light emission side of the first light emitting element 101, the second light emitting element 102, the fourth light emitting element 104, and the infrared light emitting element 103, respectively. By providing a lens for each light emitting element, the light emission efficiency of the light emitting element can be improved. The lens has light transmissivity and can be formed of, for example, an organic material such as acrylic resin, epoxy resin, or silicon resin, or an inorganic material such as silicon nitride (SiN), silicon oxynitride (SiON), or silicon oxide (SiO). The lens may have either a convex shape or a concave shape. In a case of a convex shape, a material having a lower refractive index than the material constituting the lens can be arranged on the light emission side of the lens. In particular, a gas such as air or nitrogen, a material having a low refractive index such as silica aerogel, or a vacuum state is preferable. When the convex lens is formed of a material having a high refractive index such as SiN, the light emission side of the lens can be formed of a material having a relatively low refractive index, such as an organic material such as acrylic resin, epoxy resin, or silicon resin, or an inorganic material such as silicon oxide (SiO). In a case of a concave lens, a material having a higher refractive index than the material constituting the lens can be arranged on the light emission side of the lens. The shape of the lens is not particularly limited, and a spherical shape, an aspheric shape, or another shape can be employed.

### Application Examples

Some embodiments of application examples of the light emitting device ED described above will be exemplarily described below. The light emitting device ED can be used as a constituent part of, for example, a display device or an illumination device. In addition, the light emitting device ED is applicable to an exposure light source of an electrophotographic image forming device, a backlight of a liquid crystal display device, or the like.

The display device can include an image input unit that receives image information from an area CCD, a linear CCD, a memory card, or the like, an information processing unit that processes the received image information, and a display unit that displays the received image information or processed image information, and the display unit can be configured by the light emitting device ED.

The light emitting device ED can be configured as a display unit of an image capturing device or a printer. The display unit may have a touch panel function. The driving type of the touch panel function may be an infrared type, a capacitance type, a resistive film type, or an electromagnetic induction type, and is not particularly limited. The light emitting device ED may be configured as a display unit of a multifunction printer.

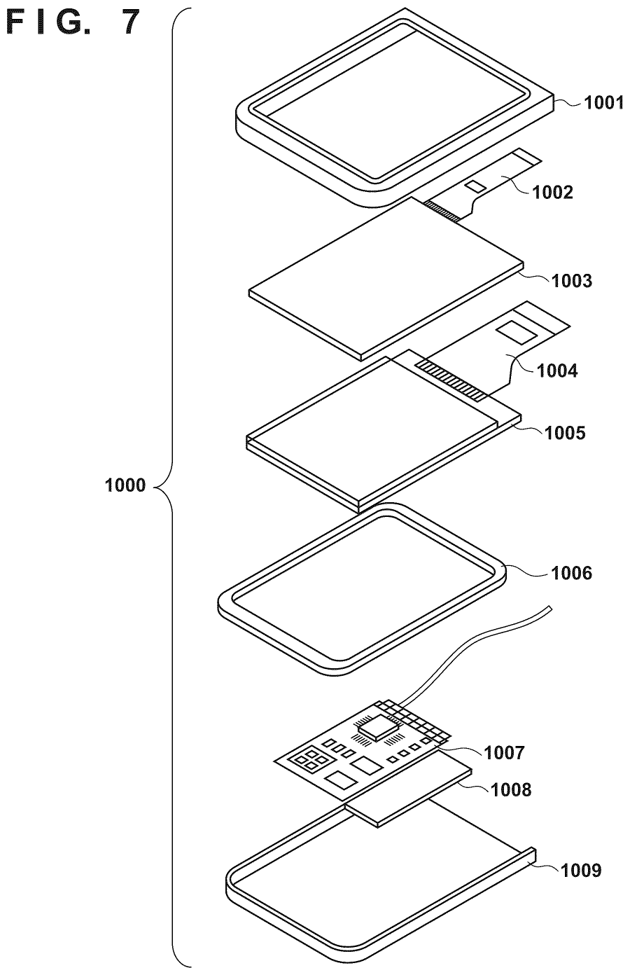

FIG. 7 shows an example in which the light emitting device ED is applied to a display device. A display device 1000 can include a touch panel 1003, a display panel 1005, a frame 1006, a circuit board 1007, and a battery 1008 between an upper cover 1001 and a lower cover 1009. The light emitting device ED can be configured as the display panel 1005. Flexible printed circuits (FPCs) 1002 and 1004 are respectively connected to the touch panel 1003 and the display panel 1005. Transistors are printed on the circuit board 1007. The battery 1008 is unnecessary if the display device 1000 is not a portable apparatus. Even when the display device 1000 is a portable apparatus, the battery 1008 may be provided at another position.

The light emitting device ED configured as the display panel 1005 may include color filters of red, green, and blue. The color filters of red, green, and blue may be arranged in a delta array.

The light emitting device ED may be configured as a display unit of a portable terminal. At this time, the light emitting device ED can be formed to have both a display function and an operation function. Examples of the portable terminal are a portable phone such as a smartphone, a tablet, and a head mounted display.

The light emitting device ED may be configured as a display unit of an image capturing device including an optical unit having a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

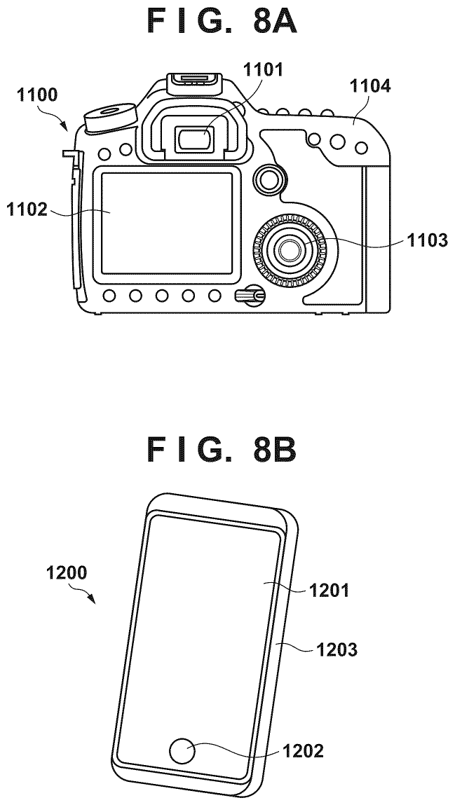

FIG. 8A is a view showing an example in which the light emitting device ED is applied to an image capturing device. An image capturing device 1100 can include a viewfinder 1101, a rear display 1102, an operation unit 1103, and a housing 1104. The viewfinder 1101 can be configured by the light emitting device ED. In this case, the viewfinder 1101 may display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display device using the organic light emitting element according to the present invention. This is so because the organic light emitting element has a high response speed. The display device using the organic light emitting element can be used for the devices that require a high display speed more preferably than for the liquid crystal display device.

The image capturing device 1100 includes an optical unit (not shown). This optical unit has a plurality of lenses, and forms an image on an image capturing element accommodated in the housing 1104. The focal points of the plurality of lenses can be adjusted by adjusting the relative positions. This operation can also automatically be performed. The image capturing device may be called a photoelectric conversion device. The photoelectric conversion device can include, as an image capturing method, not a method of sequentially capturing images but a method of detecting the difference from a preceding image, a method of extracting an image from an always recorded image, and the like.

FIG. 8B is a view showing an example in which the light emitting device ED is applied to an electronic apparatus. An electronic apparatus 1200 includes a display unit 1201, an operation unit 1202, and a housing 1203. The light emitting device ED can be configured as the display unit 1201. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic apparatus including the communication unit can also be regarded as a communication apparatus. The electronic apparatus may also have a camera function by including a lens and an image sensor. An image captured by the camera function is displayed on the display unit 1201. Examples of the electronic apparatus are a smartphone and a laptop computer.

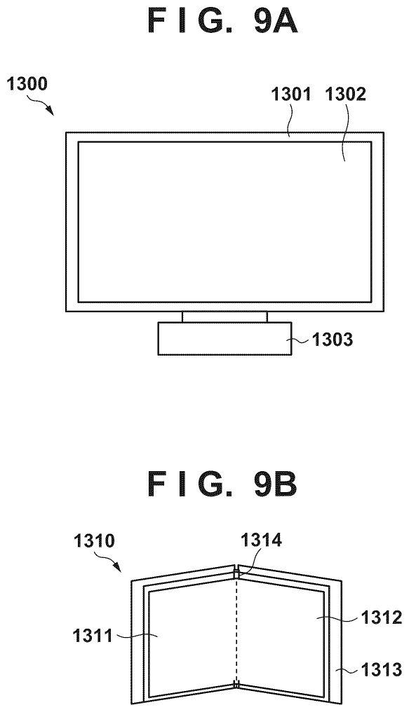

Each of FIGS. 9A and 9B shows an example in which the light emitting device ED is applied to a display device. FIG. 9A shows a display device such as a television monitor or a PC monitor. A display device 1300 includes a frame 1301 and a display unit 1302. The display unit 1302 can be configured by the light emitting device ED.

The display device 1300 includes a base 1303 that supports the frame 1301 and the display unit 1302. The base 1303 is not limited to the form shown in FIG. 9A. The lower side of the frame 1301 may also function as the base. In addition, the frame 1301 and the display unit 1302 can be bent. The radius of curvature in this case can be 5,000 mm (inclusive) to 6,000 mm (inclusive).

FIG. 9B shows another example in which the light emitting device ED is applied to a display device. A display device 1310 shown in FIG. 9B can be folded, and is a so-called foldable display device. The display device 1310 includes a first display unit 1311, a second display unit 1312, a housing 1313, and a bending point 1314. Each of the first display unit 1311 and the second display unit 1312 can be configured by the light emitting device ED. The first display unit 1311 and the second display unit 1312 can also be one seamless display device. The first display unit 1311 and the second display unit 1312 can be divided by the bending point. The first display unit 1311 and the second display unit 1312 can display different images, and the first and second display units can also display one image together.

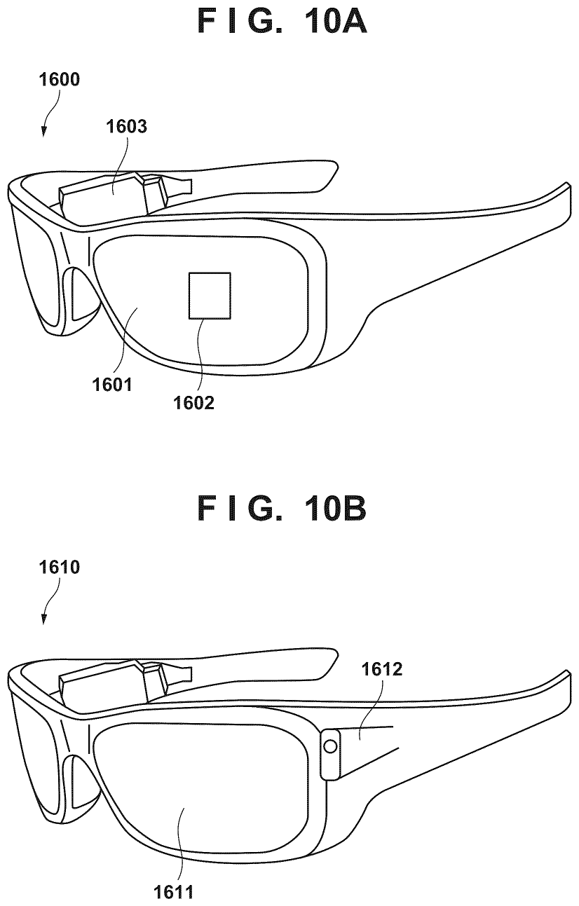

Each of FIGS. 10A and 10B shows an example in which the light emitting device ED is applied to a wearable device. The light emitting device ED can be applied to a display unit of a wearable device such as smartglasses, an HMD, or a smart contact lens. Such application examples can include an image capturing device capable of photoelectrically converting visible light and a display device capable of emitting visible light.

FIG. 10A is a view for explaining glasses 1600 (smartglasses) according to one application example. An image capturing device 1602 such as a CMOS sensor or an SPAD is provided on the surface side of a lens 1601 of the glasses 1600. In addition, the display device configured by the light emitting device ED is provided on the back surface side of the lens 1601.

The glasses 1600 further include a control device 1603. The control device 1603 functions as a power supply that supplies electric power to the image capturing device 1602 and the display device according to each embodiment. In addition, the control device 1603 controls the operations of the image capturing device 1602 and the display device. An optical system configured to condense light to the image capturing device 1602 is formed on the lens 1601.

FIG. 10B is a view for explaining glasses 1610 (smartglasses) according to another application example. The glasses 1610 include a control device 1612. An image capturing device corresponding to the image capturing device 1602 and the display device are mounted on the control device 1612. An optical system configured to project light emitted from the display device in the control device 1612 is formed in a lens 1611, and an image is projected to the lens 1611. The control device 1612 functions as a power supply that supplies electric power to the image capturing device and the display device, and controls the operations of the image capturing device and the display device. The control device may include a line-of-sight detection unit that detects the line of sight of a wearer. The detection of a line of sight may be done using infrared light emitted by the infrared light emitting element of a display device to which the light emitting device ED is applied. An infrared light emitting unit emits infrared light to an eyeball of the user who is gazing at a displayed image. An image capturing unit including a light receiving element detects reflected light of the emitted infrared light from the eyeball, thereby obtaining a captured image of the eyeball. A reduction unit for reducing light from the infrared light emitting unit to the display unit in a planar view is provided, thereby reducing deterioration of image quality.

The line of sight of the user to the displayed image is detected from the captured image of the eyeball obtained by capturing the infrared light. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to an embodiment can include an image capturing device including a light receiving element, and control an image displayed on the display device based on the line-of-sight information of the user from the image capturing device.

More specifically, the display device decides a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, it can suitably be applied to smartglasses further including an image capturing device configured to capture the outside. The smartglasses can display captured outside information in real time.

As described above, the device incorporating the light emitting device ED is advantageous in improving light emission efficiency and, for example, enables long time image display.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-036267, filed Mar. 8, 2024, which is hereby incorporated by reference herein in its entirety.

What is claimed is:

1. A light emitting device having a plurality of light emitting elements including a first light emitting element and a second light emitting element each configured to emit visible light and a third light emitting element configured to emit infrared light, wherein
each of the plurality of light emitting elements includes a reflective layer, a lower electrode arranged on the reflective layer, a light emitting layer arranged on the lower electrode, and an upper electrode arranged on the light emitting layer,
a distance from an upper surface of the reflective layer of the first light emitting element to an upper surface of the lower electrode of the first light emitting element is different from a distance from an upper surface of the reflective layer of the second light emitting element to an upper surface of the lower electrode of the second light emitting element, and
the distance from the upper surface of the reflective layer of the first light emitting element to the upper surface of the lower electrode of the first light emitting element is substantially equal to a distance from an upper surface of the reflective layer of the third light emitting element to an upper surface of the lower electrode of the third light emitting element.

2. The device according to claim 1, wherein
the light emitting layer of the third light emitting element contains an infrared light emitting material, and letting λ3 be a peak wavelength of a PL emission spectrum of the infrared light emitting material and L3 be a distance from the upper surface of the reflective layer of the third light emitting element to a lower surface of the upper electrode of the third light emitting element,
$$0.2 \leq λ3 / L 3 \leq 0.30$$
is satisfied.

3. The device according to claim 2, wherein
$$160 nm \leq L 3 \leq 300 nm$$
is satisfied.

4. The device according to claim 1, wherein
letting ND3 be an optical distance from the upper surface of the reflective layer of the third light emitting element to a lower surface of the upper electrode of the third light emitting element, φ3 be a sum of phase shifts in the reflective layer of the third light emitting element and the upper electrode of the third light emitting element, and λ3 be a peak wavelength of a PL emission spectrum of an infrared light emitting material of the light emitting layer of the third light emitting element,
$$ND 31 \leq ND 3 \leq ND 32 \\ ND 31 = - φ3 / 4 π \times λ3 \times 0.9 \\ ND 32 = - φ3 / 4 π \times λ3 \times 1.1$$
is satisfied.

5. The device according to claim 1, wherein
the light emitting layer of the first light emitting element contains a visible light emitting material, and letting λ1 be a peak wavelength of a PL emission spectrum of the visible light emitting material and L1 be a distance from the upper surface of the reflective layer of the first light emitting element to a lower surface of the upper electrode of the first light emitting element,
$$0.45 \leq λ1 / L 1 \leq 0.65$$
is satisfied.

6. The device according to claim 1, wherein
letting ND1 be an optical distance from the upper surface of the reflective layer of the first light emitting element to a lower surface of the upper electrode of the first light emitting element, φ1 be a sum of phase shifts in the reflective layer of the first light emitting element and the upper electrode of the first light emitting element, and λ1 be a peak wavelength of a PL emission spectrum of a light emitting material of the light emitting layer of the first light emitting element,
$$ND 11 \leq ND 1 \leq ND 12 \\ ND 11 = ( 1 - φ1 / 2 π ) \times λ1 \times 0.9 \\ ND 12 = ( 1 - φ1 / 2 π ) \times λ1 \times 1.1$$
is satisfied.

7. The device according to claim 1, wherein
the first light emitting element is a blue light emitting element.

8. The device according to claim 1, wherein
the first light emitting element includes a light transmitting layer arranged between the reflective layer and the lower electrode, and
the third light emitting element includes a light transmitting layer arranged between the reflective layer and the lower electrode.

9. The device according to claim 8, wherein
a thickness of the light transmitting layer of the first light emitting element is substantially equal to a thickness of the light transmitting layer of the third light emitting element, and
a thickness of the lower electrode of the first light emitting element is substantially equal to a thickness of the lower electrode of the third light emitting element.

10. The device according to claim 1, wherein
a light emitting material contained in the light emitting layer of the first light emitting element and a light emitting material contained in the light emitting layer of the third light emitting element are different from each other.

11. The device according to claim 1, wherein
the reflective layer of the first light emitting element and the lower electrode of the first light emitting element are in contact, and the reflective layer of the third light emitting element and the lower electrode of the third light emitting element are in contact.

12. The device according to claim 1, wherein
the first light emitting element and the third light emitting element are arranged adjacent to each other,
the lower electrode of the first light emitting element and the lower electrode of the third light emitting element are separated from each other by an insulating layer, and
the insulating layer has a T-shape in a section cutting the reflective layer, the lower electrode, the light emitting layer, and the upper electrode.

13. The device according to claim 12, wherein
the insulating layer has a flat upper surface.

14. A light emitting device having a plurality of light emitting elements including a first light emitting element configured to emit visible light, a second light emitting element configured to emit visible light of a wavelength different from the first light emitting element, and a third light emitting element configured to emit infrared light, wherein
each of the plurality of light emitting elements includes a reflective layer, a lower electrode arranged on the reflective layer, a light emitting layer arranged on the lower electrode, and an upper electrode arranged on the light emitting layer,
a distance from an upper surface of the reflective layer of the first light emitting element to an upper surface of the lower electrode of the first light emitting element is a first distance,
a distance from an upper surface of the reflective layer of the second light emitting element to an upper surface of the lower electrode of the second light emitting element is a second distance,
a distance from an upper surface of the reflective layer of the third light emitting element to an upper surface of the lower electrode of the third light emitting element is a third distance, and
a difference between the first distance and the third distance is smaller than a difference between the first distance and the second distance.

15. The device according to claim 14, wherein
the first distance is substantially equal to the third distance.

16. The device according to claim 15, wherein
the first light emitting element and the third light emitting element are arranged adjacent to each other,
the lower electrode of the first light emitting element and the lower electrode of the third light emitting element are separated from each other by an insulating layer, and
the insulating layer has a T-shape in a section cutting the reflective layer, the lower electrode, the light emitting layer, and the upper electrode.

17. The device according to claim 16, wherein
the insulating layer has a flat upper surface.

18. A light emitting device having a plurality of light emitting elements including a red light emitting element configured to emit red light and an infrared light emitting element configured to emit infrared light, wherein
each of the plurality of light emitting elements includes a reflective layer, a lower electrode arranged on the reflective layer, a light emitting layer arranged on the lower electrode, and an upper electrode arranged on the light emitting layer, and
a distance from an upper surface of the reflective layer of the infrared light emitting element to an upper surface of the lower electrode of the infrared light emitting element is smaller than a distance from an upper surface of the reflective layer of the red light emitting element to an upper surface of the lower electrode of the red light emitting element.

19. The device according to claim 1, wherein
the device is configured as a display device.

20. An image capturing device comprising an optical unit including a plurality of lenses, an image sensor configured to receive light having passed through the optical unit, and a display unit configured to display an image,
wherein the display unit displays an image captured by the image sensor, and includes a light emitting device defined in claim 1.

21. An electronic apparatus comprising a housing provided with a display unit, and a communication unit provided in the housing and configured to perform external communication,
wherein the display unit includes a light emitting device defined in claim 1.

22. A wearable device comprising a display device configured to display an image,
wherein the display device includes a light emitting device defined in claim 1.
